(19) United States
(12) Patent Application Publication
(10) Pub. No.: US 2012/0261175 A1
(43) Pub. Date: Oct. 18, 2012

(54) PRINTED CIRCUIT BOARD

(75) Inventors: TSUNG-SHENG HUANG, Tu-Cheng (TW); CHUN-JEN CHEN, Tu-Cheng (TW); DUEN-YI HO, Tu-Cheng (TW); WEI-CHIEH CHOU, Tu-Cheng (TW)

(73) Assignee: HON HAI PRECISION INDUSTRY CO., LTD., Tu-Cheng (TW)

(21) Appl. No.: 13/156,348

(22) Filed: Jun. 9, 2011

(30) Foreign Application Priority Data
Apr. 15, 2011 (TW) 100113080

(51) Int. Cl. H05K 1/11

(52) U.S. Cl. 174/261

(57) ABSTRACT

A printed circuit board includes a first circuit area, a second circuit area, a plurality of connectors, and a connecting terminal. The first circuit area is electrically connected to the second circuit area via the connectors. The connecting terminal is placed on one side of the first circuit area for electrically connecting with a load. An imaginary center line of the connecting terminal is perpendicular to the one side of the printed circuit board. The less a horizontal distance between the center line of connecting terminal and one of the connectors, the larger a vertical distance between the side of the printed circuit board and the one of the connector.

### BACKGROUND

1. Technical Field

The present disclosure relates to a printed circuit board (PCB).

2. Description of Related Art

Referring to FIG. 4, a conventional PCB includes a first circuit area 11, a second circuit area 12 and a connecting terminal 13. The connecting terminal 13 is placed on one side of the first circuit area 11, for electrically connecting a load. The first circuit area 11 and the second circuit area 12 have different operating current, but the operating voltage of them may be identical, such as 12V. Since the load need high driving current, the first circuit area 11 is generally connected to the second circuit area 12 via a number of connectors 14, 15, 16, 17, 18. However, the current passing through the connectors 14, 15, 16, 17, 18 is not completely uniform, resulting in high temperature at some portions of the circuit board, which may cause the PCB unstable or even damage the PCB.

What is needed, therefore, is a circuit board which can overcome the limitations described above.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of a first exemplary embodiment of a printed circuit board.

FIG. 2 is a schematic diagram of a second exemplary embodiment of a printed circuit board.

FIG. 3 is a schematic diagram of a third exemplary embodiment of a printed circuit board.

FIG. 4 is a schematic diagram of a conventional printed circuit board.

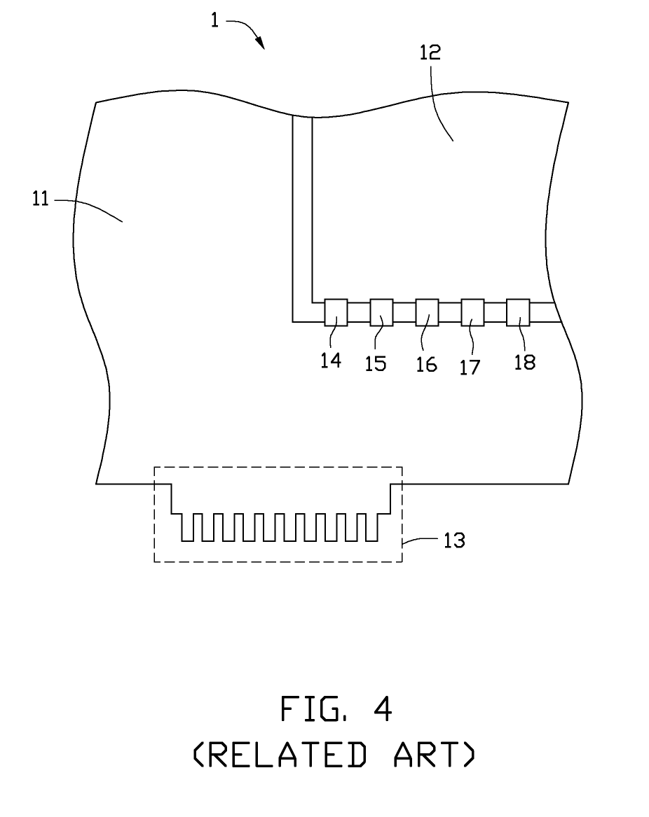

### DETAILED DESCRIPTION

The disclosure, including the accompanying drawings, is illustrated by way of example and not by way of limitation. It should be noted that references to one embodiment in this disclosure are not necessarily to the same embodiment, and such references mean at least one.

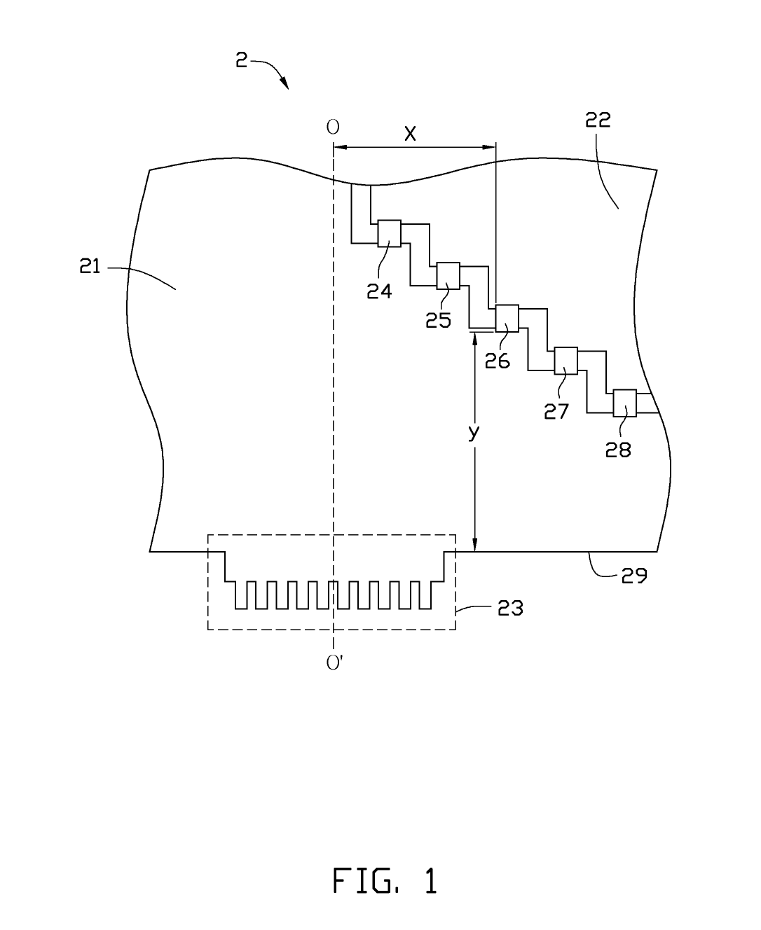

Referring to FIG. 1, a first exemplary embodiment of a printed circuit board (PCB) 2 includes a first circuit area 21, a second circuit area 22 and a number of connectors 24, 25, 26, 27, 28. It can be understood that the number of the connectors is a matter of design, and can be two or more according to the demand of practical application.

The printed circuit board 2 further includes a connecting terminal 23. The connecting terminal 23 is placed on one side 29 of the first circuit area 21, for electrically connecting a load (not shown). The printed circuit board 2 can deliver the driving current into the load via the connecting terminal 23, so the connecting terminal 23 can be considered as a load port. The connecting terminal 23 can be a golden finger meeting Universal Serial Bus (USB), Peripheral Component Interconnect (PCI) or other standards. The connecting terminal 23 has an imaginary center line OO′ perpendicular to the side 29 of the printed circuit board 2.

In present embodiment, the operation current of the first circuit area 21 with the connecting terminal 23 formed thereon is greater than that of the second circuit area 22. The first circuit area 21 is electrically connected to the second circuit area 22 via the connectors 24, 25, 26, 27, 28. That is, the current in the second circuit area 22 flows into the first circuit area 21 by passing through the connectors 24, 25, 26, 27, 28, and further gathers to the connecting terminal 23.

The connectors 24, 25, 26, 27, 28 may be resistances, metal-oxide-semiconductor field-effect transistors (MOSFETs) or other impedance components. Based on the distribution of the connection area between the first circuit area 21 and the second circuit area 22, the connectors 24, 25, 26, 27, 28 are to be arranged in such manner, the less a horizontal distance x between the center line OO′ of connecting terminal 23 and one of the connectors 24, 25, 26, 27, 28 is, the larger a vertical distance y between the side 29 of the printed circuit board 2 and that the one connector 24, 25, 26, 27, 28 should be. It can be understood that, the more the connectors 24, 25, 26, 27, 28 close to the center line OO′ of connecting terminal 23, the more the vertical distance y between that connector and the side 29 of the printed circuit board 2, the larger an equivalent resistance between that connector and connecting terminal 23. In present embodiment, the connectors 24, 25, 26, 27, 28 are arranged in steps, which mean that distances between the connectors 24, 25, 26, 27, 28 and center of the connecting terminal 23 (not shown) are almost the same.

Because the current flows into the first circuit area 21 by passing through the connectors 24, 25, 26, 27, 28 would gather to the connecting terminal 23 in a sector whose center coincides with the connecting terminal 23, and the closest connector to the center line OO′ of connecting terminal 23 has larger equivalent resistance, that means the path in the first circuit area 21 with high current density in relation to the connecting terminal 23 has larger equivalent resistance. Therefore, the current in the path of the first circuit area 21 which has higher current density and closer to the center line OO′ of connecting terminal 23 can be conducted into the connectors which are farther from the center line OO′ of connecting terminal 23, such that the current passes through each of the connectors 24, 25, 26, 27, 28 is almost the same, and the current flows into the connecting terminal 23 is uniform, or effectively so, such that high temperature created at one of the connectors 24, 25, 26, 27, 28 can be avoided, the reliability and lifespan of the printed circuit board 2 can be improved.

A current at each connector 24, 25, 26, 27, 28 is obtained based on an exemplary experiment are illustrated as follows in table 1:

TABLE 1

| | Connector | | | | |
|---|---|---|---|---|---|
| | 24 | 25 | 26 | 27 | 28 |
| Current(A) | 7.8615 | 8.0822 | 7.6984 | 7.6779 | 8.6801 |

As a result, the current passes through each of the connectors 24, 25, 26, 27, 28 is almost the same, thus avoiding a greater current at one of the connectors 24, 25, 26, 27, 28.

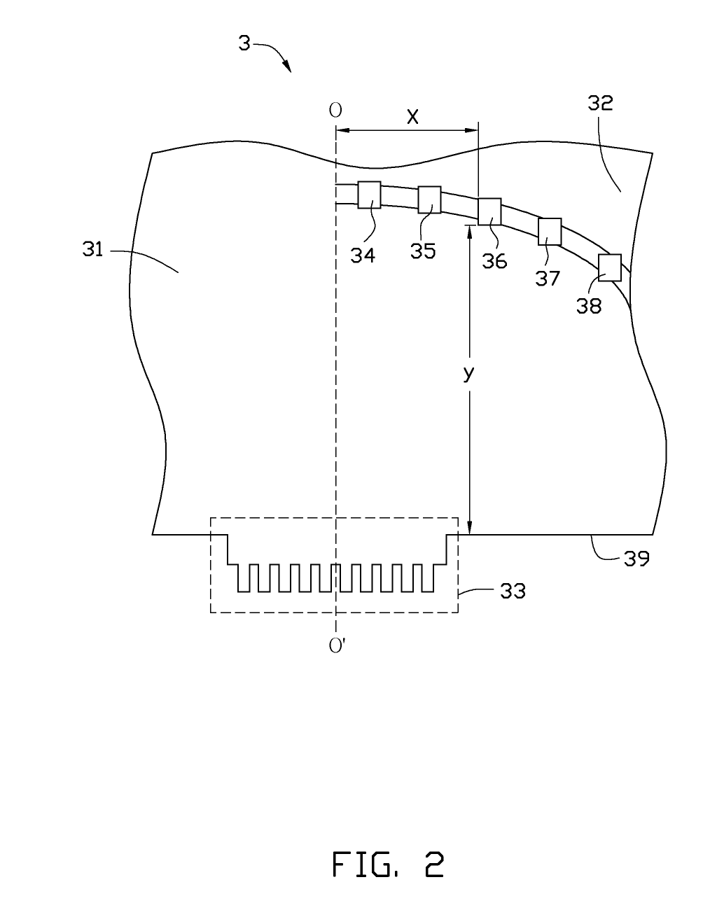

Referring to FIG. 2, a printed circuit board 3 in accordance with a second embodiment is provided. The printed circuit board 3 is similar to the printed circuit board 2 of the first embodiment, except the arrangement for the connectors 34, 35, 36, 37, 38. The connectors 34, 35, 36, 37, 38 in the second embodiment are arranged in arc shaped. The less a horizontal distance χ between the center line OO′ of connecting terminal 33 and one of the connectors 34, 35, 36, 37, 38, the larger a vertical distance y between the side 39 of the printed circuit board 3 and that connector. Similar with the first embodiment, the current in the path of the first circuit area 31 which has higher current density and closer to the center line OO′ of connecting terminal 33 can be conducted into the connectors which are farther from the center line OO′ of connecting terminal 33, such that the current passes through each of the connectors 34, 35, 36, 37, 38 is almost the same, and the current flows into the connecting terminal 33 is uniform, or effectively so, such that high temperature created at one of the connectors 34, 35, 36, 37, 38 can be avoided, the reliability and lifespan of the printed circuit board 3 can be improved.

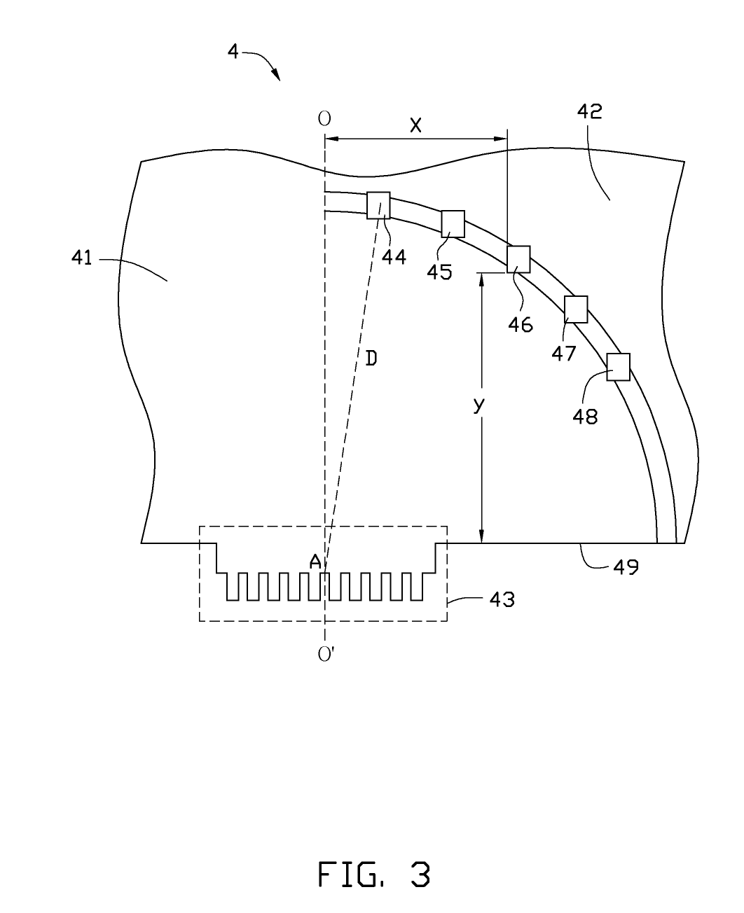

Referring to FIG. 3, a printed circuit board 4 in accordance with a third embodiment is provided. The printed circuit board 4 is similar to the printed circuit board 2 of the first embodiment, except the arrangement for the connectors 44, 45, 46, 47, 48. The connectors 44, 45, 46, 47, 48 are arranged on a suppositional circular arc with the center A on the connecting terminal 43 and a predetermined radius. Specifically, a line distance between each of the connectors 44, 45, 46, 47, 48 and the connecting terminal 43 is almost the same. The dot A of the suppositional circular arc may be coincident with any point on the connecting terminal 43. The distance D can be determined based on the arrangement/distribution for the connection of the first circuit area 41 and the second circuit area 42. The less a horizontal distance x between the center line OO′ of connecting terminal 43 and one of the connectors 44, 45, 46, 47, 48, the larger a vertical distance y between the side 49 of the printed circuit board 4 and that connector. Similar with the first embodiment, the current in the path of the first circuit area 41 which has higher current density and closer to the center line OO′ of connecting terminal 43 can be conducted into the connectors which are father from the center line OO′ of connecting terminal 43, such that the current passes through each of the connectors 44, 45, 46, 47, 48 is almost the same, and the current flows into the connecting terminal 43 is uniform, or effectively so, such that high temperature created at one of the connectors 44, 45, 46, 47, 48 can be avoided, the reliability and lifespan of the printed circuit board 4 can be improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising a first circuit area, a second circuit area, a plurality of connectors, and a connecting terminal, the first circuit area being electrically connected to the second circuit area via the connectors, the connecting terminal being placed on a side of the first circuit area for electrically connecting with a load, an imaginary center line of the connecting terminal being perpendicular to the one side of the printed circuit board, the less a horizontal distance between the center line of connecting terminal and one of the connectors, the larger a vertical distance between the side of the printed circuit board and the one of the connectors.

2. The printed circuit board of claim 1, wherein the connectors are arranged in steps.

3. The printed circuit board of claim 1, wherein the connectors are arranged in arc shaped.

4. The printed circuit board of claim 1, wherein the connectors are arranged on a suppositional circular arc with the center on the connecting terminal and a predetermined radius.

5. The printed circuit board of claim 1, wherein the connecting terminal is a golden finger meeting Universal Serial Bus or Peripheral Component Interconnect standard.

6. The printed circuit board of claim 1, wherein the operation current of the first circuit area is greater than that of the second circuit area.
